(19) United States
(12) Patent Application Publication
(10) Pub. No.: US 2024/0145337 A1
(43) Pub. Date: May 2, 2024

(54) SEMICONDUCTOR DEVICE ASSEMBLY WITH A THERMALLY-CONDUCTIVE CHANNEL

(71) Applicant: Micron Technology, Inc., Boise, ID (US)

(72) Inventors: Koustav SINHA, Boise, ID (US); Walter L. MODEN, Boise, ID (US); Christopher GLANCEY, Boise, ID (US); Quang NGUYEN, Boise, ID (US)

(21) Appl. No.: 18/496,562

(22) Filed: Oct. 27, 2023

Related U.S. Application Data
(60) Provisional application No. 63/382,007, filed on Nov. 2, 2022.

(51) Int. Cl. H01L 23/373; H01L 23/00; H01L 23/367

(52) U.S. Cl. CPC H01L 23/3736; H01L 23/3675; H01L 24/32; H01L 24/48; H01L 24/73; H01L 2224/32225; H01L 2224/48225; H01L 2224/73215

(57) ABSTRACT

Implementations described herein relate to various semiconductor device assemblies. In some implementations, a semiconductor device assembly includes a substrate having a bore that extends through the substrate. The semiconductor device assembly may include a semiconductor die disposed on the substrate. The semiconductor device assembly may include a thermally-conductive channel extending through the bore, the thermally-conductive channel having a first end located at a same side of the substrate as the semiconductor die, and a second end located at an opposite side of the substrate from the semiconductor die.

### CROSS-REFERENCE TO RELATED APPLICATION

This patent application claims priority to U.S. Provisional Patent Application No. 63/382,007, filed on Nov. 2, 2022, and entitled “SEMICONDUCTOR DEVICE ASSEMBLY WITH A THERMALLY-CONDUCTIVE CHANNEL.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to a semiconductor device assembly with a thermally-conductive channel.

### BACKGROUND

A semiconductor package includes a casing that contains one or more semiconductor devices, such as integrated circuits. Semiconductor device components may be fabricated on semiconductor wafers before being diced into dies and then packaged. A semiconductor package protects internal components from damage and includes means for connecting internal components to external components (e.g., a circuit board), such as via balls, pins, or leads. A semiconductor package is sometimes referred to as a semiconductor device assembly.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus.

FIG. 4 is a diagram of an example apparatus with a thermally-conductive channel.

FIG. 5 is a diagram of an example apparatus with a thermally-conductive channel.

FIG. 6 is a diagram of an example apparatus with a thermally-conductive channel.

FIG. 7A is a cross-sectional view of an example apparatus with a thermally-conductive channel.

FIG. 7B is a cross-sectional view of an example apparatus with multiple thermally-conductive channels.

FIG. 7C is a cross-sectional view of an example apparatus with a thermally-conductive channel.

FIG. 8 is a flowchart of an example method of forming an integrated assembly or apparatus with a thermally-conductive channel.

FIG. 9 is a flowchart of an example method of forming an integrated assembly or apparatus with a thermally-conductive channel.

FIG. 10 is a diagram of an example process of forming an apparatus with a thermally-conductive channel.

### DETAILED DESCRIPTION

Semiconductor devices may reach high operating temperatures due to densely packed electronics, as well as high operating speeds and frequencies. In some cases, the operating temperature of a semiconductor device may exceed a specified maximum temperature at which operation of the semiconductor device is optimal. Thus, at excessive operating temperatures, a structure and/or a functionality of the semiconductor device may suffer. This may be exacerbated in automotive applications or graphics applications where semiconductor devices may operate at higher power or under severe conditions for extended time periods. In some cases, a heat sink may be used to remove heat from a semiconductor device. However, a conventional heat sink may be unable to handle the excessive heat generated by a semiconductor device.

Some implementations described herein provide a semiconductor device assembly that includes a semiconductor die and a thermally-conductive channel configured to transfer heat from the semiconductor die to a circuit board (e.g., a printed circuit board (PCB)). In some implementations, the semiconductor die may be disposed on a substrate that has a bore extending through the substrate, and the thermally-conductive channel may extend through the bore, between the semiconductor die and the circuit board, to thereby transfer heat from the semiconductor die to the circuit board. The bore in the substrate may be used for running one or more wire bonds from a bottom of the semiconductor die to a bottom of the substrate in a board-on-chip configuration of the semiconductor device assembly, where a connection of the semiconductor device assembly to the circuit board is via a ball grid array. Accordingly, in some implementations, the bore may be filled with a wire bond encapsulant to protect the wire bonds, and the thermally-conductive channel may extend through the wire bond encapsulant that is in the bore.

The thermally-conductive channel may improve heat dissipation from the semiconductor die. In this way, an operating temperature of the semiconductor device assembly may be reduced (e.g., to within a temperature range associated with optimal operation of the semiconductor device assembly), thereby improving a functionality of the semiconductor device assembly.

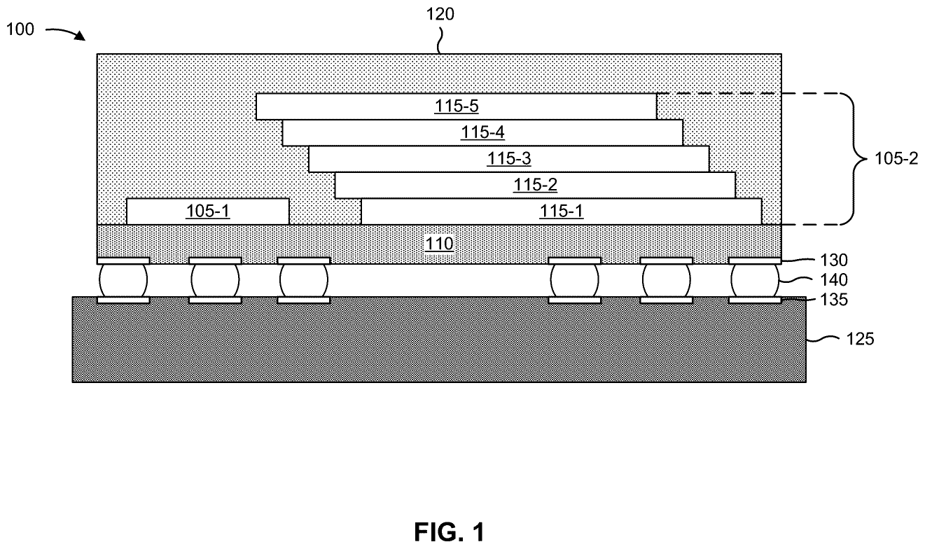

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

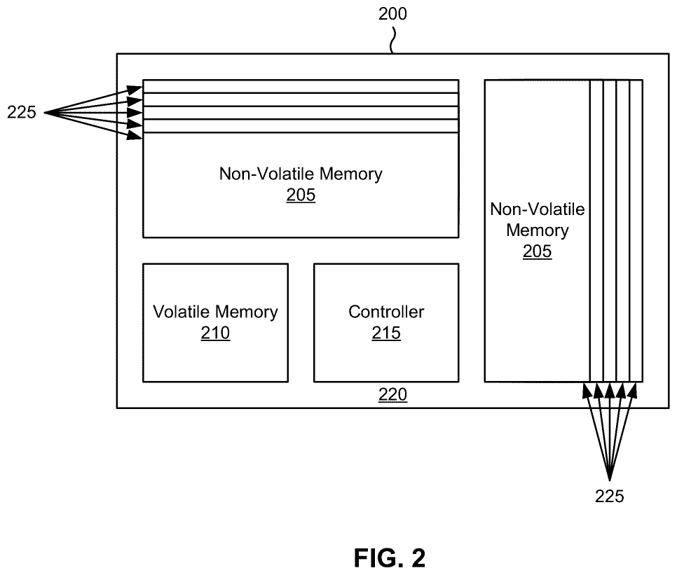

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

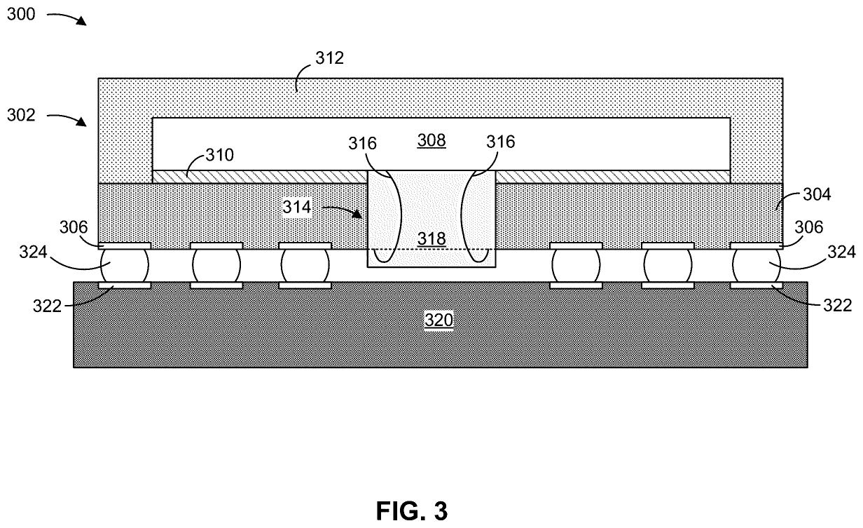

FIG. 3 is a diagram of an example apparatus 300. The apparatus 300 may correspond to, or may be similar to, the apparatus 100. The apparatus 300 may include a semiconductor device assembly 302. The semiconductor device assembly 302 may include a substrate 304 that includes electrical contacts 306 (e.g., bond pads), in a similar manner as described in connection with FIG. 1. A semiconductor die 308 may be disposed on the substrate 304, in a similar manner as described in connection with FIG. 1. In some implementations, a die attach film (DAF) 310 may be between the semiconductor die 308 and the substrate 304 to facilitate attachment of the semiconductor die 308 to the substrate 304. A casing 312 (e.g., a package encapsulant) may surround the semiconductor die 308, in a similar manner as described in connection with FIG. 1.

The substrate 304 may have a bore 314 that extends through the substrate 304. One or more wire bonds 316 may extend through the bore 314 to electrically connect the semiconductor die 308 and the substrate 304. As shown, the wire bonds 316 may electrically connect a bottom (e.g., underside) of the semiconductor die 308 to a bottom (e.g., underside) of the substrate 304. That is, the semiconductor device assembly 302 may be in a board-on-chip configuration. An encapsulant 318 (e.g., a wire bond encapsulant) may extend through (e.g., fill) the bore 314 to protect the wire bonds 316.

The apparatus 300 may include a circuit board 320 (e.g., a PCB). The circuit board 320 may include electrical contacts 322 (e.g., bond pads), in a similar manner as described in connection with FIG. 1. The semiconductor device assembly 302 may be mounted on, and electrically connected to, the circuit board 320 (e.g., via a ball grid array). For example, the electrical contacts 306 of the substrate 304 may be electrically connected to the electrical contacts 322 of the circuit board 320 using solder balls 324 arranged in a ball grid array, in a similar manner as described in connection with FIG. 1. Additionally, or alternatively, the substrate 304 may be electrically connected to the circuit board 320 using another type of connector, in a similar manner as described in connection with FIG. 1.

As described above, the semiconductor device assembly 302 may generate excessive heat during operation, which may impair a functionality of the semiconductor device assembly 302 and/or degrade a structure of the semiconductor device assembly 302. Some implementations described herein address these and other issues.

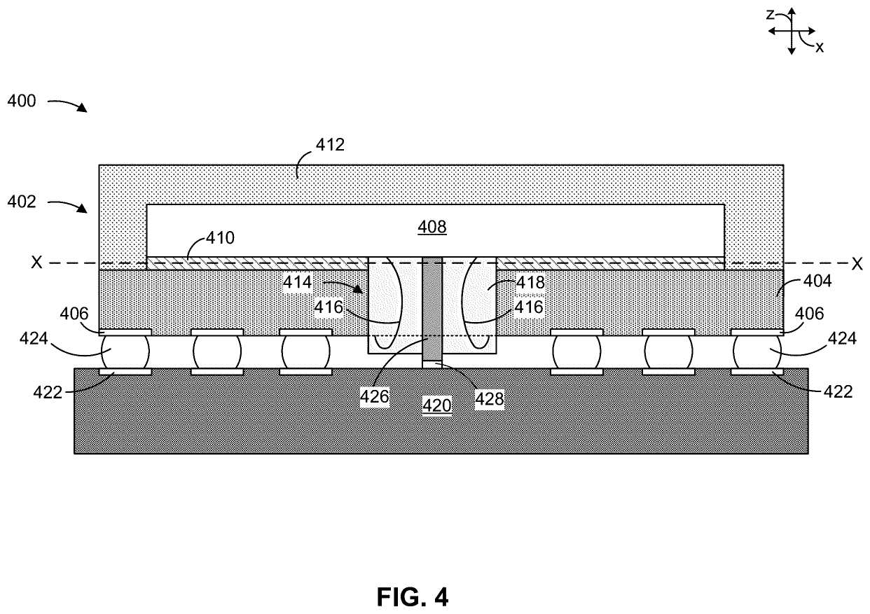

FIG. 4 is a diagram of an example apparatus 400 having a thermally-conductive channel. The apparatus 400 may correspond to, or may be similar to, the apparatus 100. The apparatus 400 may include a semiconductor device assembly 402. The semiconductor device assembly 402 may include a substrate 404 that includes electrical contacts 406 (e.g., bond pads), in a similar manner as described in connection with FIG. 1. A semiconductor die 408 may be disposed on the substrate 404, in a similar manner as described in connection with FIG. 1. In some implementations, a DAF 410 may be between the semiconductor die 408 and the substrate 404 to facilitate attachment of the semiconductor die 408 to the substrate 404. A casing 412 (e.g., a package encapsulant) may surround the semiconductor die 408, in a similar manner as described in connection with FIG. 1.

The substrate 404 may have a bore 414 that extends through the substrate 404. One or more wire bonds 416 may extend through the bore 414 to electrically connect the semiconductor die 408 and the substrate 404. As shown, the wire bonds 416 may electrically connect a bottom (e.g., underside) of the semiconductor die 408 to a bottom (e.g., underside) of the substrate 404. That is, the semiconductor device assembly 402 may be in a board-on-chip configuration. An encapsulant 418 (e.g., a wire bond encapsulant) may extend through (e.g., fill) the bore 414 to encapsulate (e.g., to protect) the wire bonds 416.

The apparatus 400 may include a circuit board 420 (e.g., a PCB). The circuit board 420 may include electrical contacts 422 (e.g., bond pads), in a similar manner as described in connection with FIG. 1. The semiconductor device assembly 402 may be mounted on, and electrically connected to, the circuit board 420. That is, the substrate 404 may be electrically connected to the circuit board 420 (e.g., via a ball grid array). For example, the electrical contacts 406 of the substrate 404 may be electrically connected to the electrical contacts 422 of the circuit board 420 using solder balls 424 arranged in a ball grid array, in a similar manner as described in connection with FIG. 1. Additionally, or alternatively, the substrate 404 may be electrically connected to the circuit board 420 using another type of connector, in a similar manner as described in connection with FIG. 1.

The semiconductor device assembly 402 may include a thermally-conductive channel 426. The thermally-conductive channel 426 may be configured to transfer heat from the semiconductor die 408 to the circuit board 420. The thermally-conductive channel 426 may include a material with high thermal conductivity. For example, the thermally-conductive channel 426 may comprise, consist of, or consist essentially of copper. Additionally, or alternatively, the thermally-conductive channel 426 may comprise, consist of, or consist essentially of aluminum, magnesium, gold, and/or graphite, among other examples. The thermally-conductive channel 426 may be in the shape of a rod (e.g., a cylindrical rod, a rectangular rod, or the like).

The thermally-conductive channel 426 may extend through the bore 414 (e.g., between the semiconductor die 408 and the circuit board 420). For example, the thermally-conductive channel 426 may extend through the encapsulant 418. As shown, the thermally-conductive channel 426 may have a first end located at a same side of the substrate 404 as the semiconductor die 408 and a second end located at an opposite side of the substrate 404 from the semiconductor die 408. The thermally-conductive channel 426 (e.g., the first end of the thermally-conductive channel 426) may have a thermal connection to the semiconductor die 408. For example, the thermally-conductive channel 426 (e.g., the first end of the thermally-conductive channel 426) may contact (e.g., thermally contact) the semiconductor die 408 (e.g., the bottom of the semiconductor die 408). Here, the thermally-conductive channel 426 (e.g., the first end of the thermally-conductive channel 426) may be bonded to the semiconductor die 408. In some implementations, the thermally-conductive channel 426 may be bonded to the bottom of the semiconductor die 408 that is in contact with the encapsulant 418 but not the conductive pads that are coupled to the wire bonds 416. As another example, an air gap may be between the thermally-conductive channel 426 (e.g., the first end of the thermally-conductive channel 426) and the semiconductor die 408 (e.g., the air gap may be sufficiently small to allow heat transfer by radiation from the semiconductor die 408 to the thermally-conductive channel 426).

Although the thermally-conductive channel 426 is shown in FIG. 4 as being linear (e.g., extending along the z-axis shown), in some implementations, the thermally-conductive channel 426 may be non-linear. For example, the thermally-conductive channel 426 may include one or more angled portions (e.g., angled relative to the z-axis shown and/or the x-axis shown), one or more orthogonal portions (e.g., extending along the x-axis shown), or the like, to accommodate routing of the wire bonds 416. In some implementations, the thermally-conductive channel 426 may include one or more cut-out portions (e.g., such that a surface of the thermally-conductive channel 426 has one or more valleys, recesses, or the like) and/or one or more holes through an interior of the thermally-conductive channel 426, or the like, to accommodate routing of the wire bonds 416.

In some implementations, a thermal interface material (TIM) 428 may be disposed on the circuit board 420. The thermally-conductive channel 426 (e.g., the second end of the thermally-conductive channel 426) may contact (e.g., thermally contact) the TIM 428. The TIM 428 may comprise, consist of, or consist essentially of conductive adhesive, solder, or the like. In some implementations, a thermal connection of the thermally-conductive channel 426 to the circuit board 420 (e.g., to the TIM 428) may be at a gap (e.g., of approximately 400 micrometers) between a first row of electrical contacts 422 (e.g., bond pads) of the circuit board 420 and a second row of electrical contacts 422 (e.g., bond pads) of the circuit board 420.

During operation of the semiconductor device assembly 402, the thermally-conductive channel 426 may transfer heat generated by the semiconductor die 408 to the circuit board 420, where the heat can be dissipated faster and more efficiently than from the semiconductor die 408. In this way, an operating temperature of the semiconductor device assembly 402 may be reduced, thereby preserving the functionality of the semiconductor device assembly 402.

As indicated above, FIG. 4 is provided as an example. Other examples may differ from what is described with respect to FIG. 4.

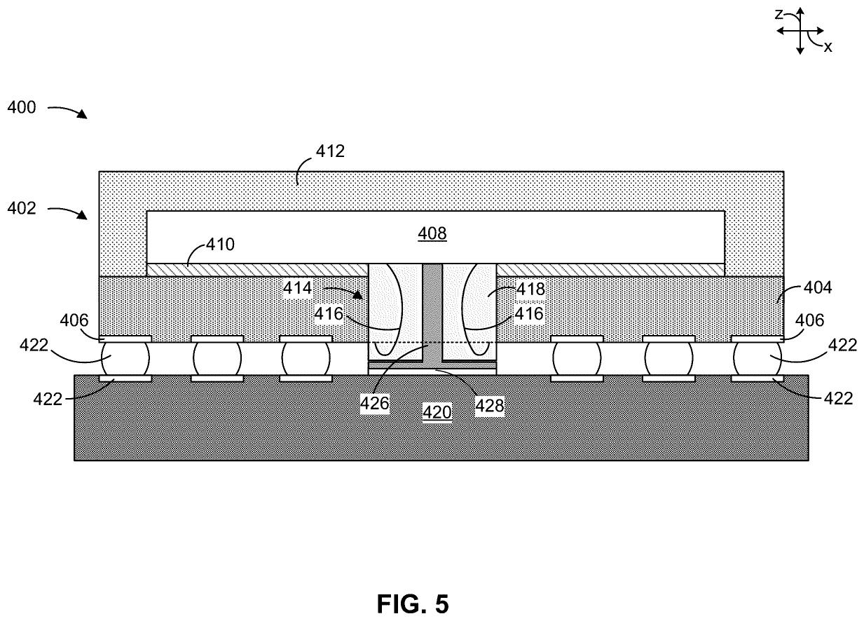

FIG. 5 is a diagram of the example apparatus 400 having the thermally-conductive channel. In particular, FIG. 5 shows the example apparatus 400 with a variation of the thermally-conductive channel 426. As shown, the thermally-conductive channel 426 may include a narrower portion (e.g., that includes the first end of the thermally-conductive channel 426) and a wider portion (e.g., that includes the second end of the thermally-conductive channel 426). For example, the thermally-conductive channel 426 may be in the shape of an inverted “T.” A width of the wider portion may be wider (e.g., at least four times wider) than a width of the narrower portion. A height of the narrower portion may be taller (e.g., at least ten times taller) than a height of the wider portion. In some implementations, a width of the wider portion may correspond to a width of the encapsulant 418 (e.g., a width of the bore 414). As shown, the wider portion of the thermally-conductive channel 426 may have a thermal connection to the circuit board 420, and a width of the TIM 428 may also be wider (relative to what is shown in FIG. 4). For example, a width of the TIM 428 may correspond to a width of the wider portion of the thermally-conductive channel 426. In some implementations, an air gap may be maintained between a top of the wider portion and a bottom of the encapsulant 418 (e.g., to promote thermal transfer down to the circuit board 420). The wider portion of the thermally-conductive channel 426 may increase a surface area of the thermally-conductive channel 426 that is thermally connected to the circuit board 420, thereby improving heat dissipation from the semiconductor die 408. Similar to the implementation in FIG. 5, the thermally-conductive channel 426 may also be in the shape of an “I” in some implementations (e.g., with wider portions at both ends of the narrower portion).

As indicated above, FIG. 5 is provided as an example. Other examples may differ from what is described with respect to FIG. 5.

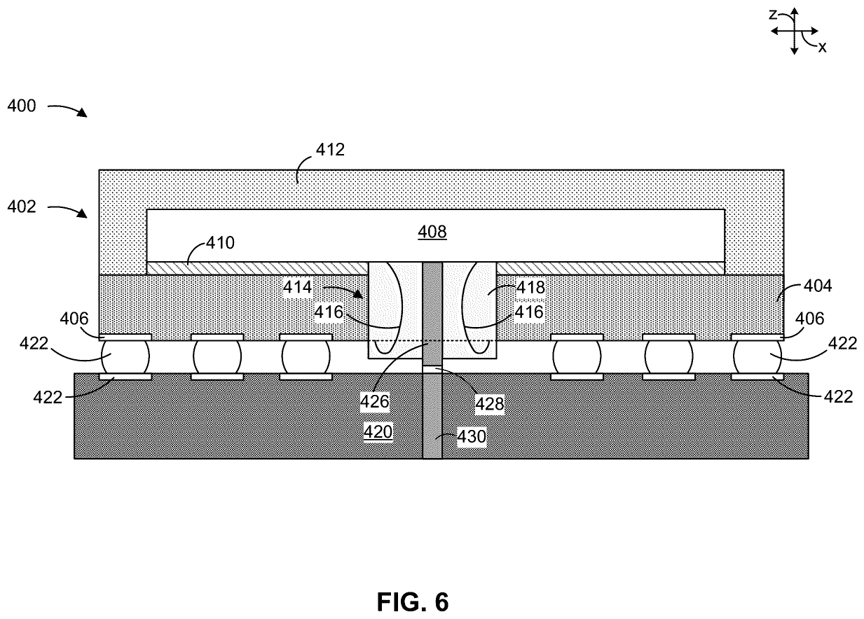

FIG. 6 is a diagram of the example apparatus 400 having the thermally-conductive channel. In particular, FIG. 6 shows the example apparatus 400 with a variation of the circuit board 420. As shown, the circuit board 420 may include a via 430 (e.g., a plated via) in the circuit board 420. The via 430 may be a through-hole via, as shown, a blind via, or the like. The via 430 may be aligned with the thermally-conductive channel 426. The thermally-conductive channel 426 may have a thermal connection to the via 430. For example, the TIM 428 may connect the thermally-conductive channel 426 to the via 430. The via 430 may facilitate spreading of heat transferred from the thermally-conductive channel 426 over a greater area of the circuit board 420, thereby improving heat dissipation at the circuit board 420.

As indicated above, FIG. 6 is provided as an example. Other examples may differ from what is described with respect to FIG. 6.

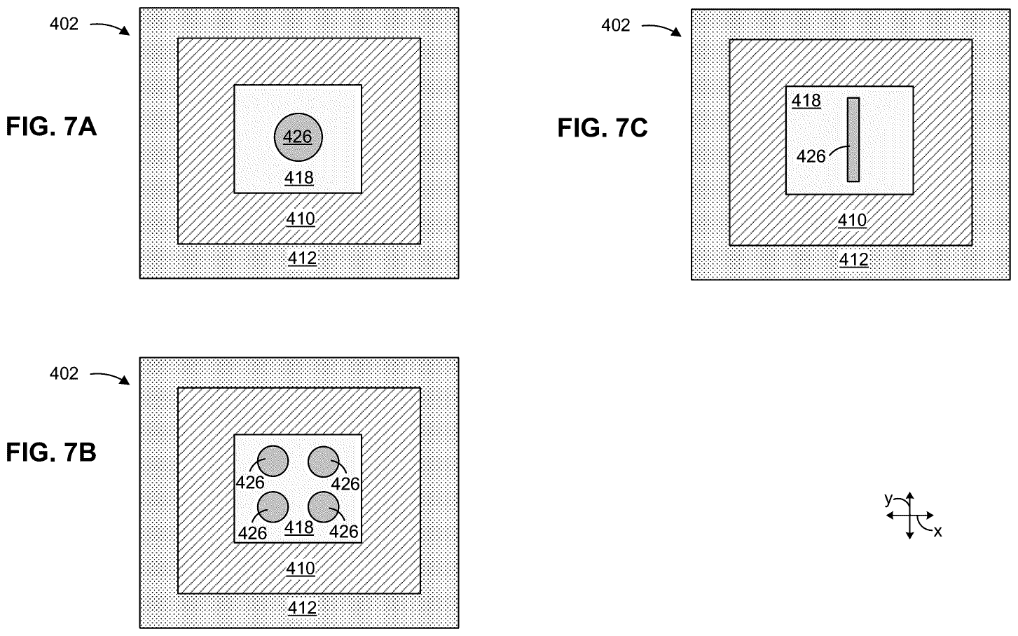

FIG. 7A is a cross-sectional view of the example apparatus 400, having the thermally-conductive channel, taken along line X-X (shown in FIG. 4). As shown, the semiconductor device assembly 402 may include a single thermally-conductive channel 426. In some implementations, the thermally-conductive channel 426 may be centrally located in the encapsulant 418, as shown. In some implementations, the thermally-conductive channel 426 may be aligned with an area of the semiconductor die 408 that is associated with a higher operating temperature (e.g., a hot spot) than an operating temperature of another area of the semiconductor die 408. In other words, testing of the semiconductor device assembly 402 may identify at least one area of the semiconductor die 408 that generates greater (e.g., excessive) heat during operation (e.g., an amount of heat that satisfies a threshold). Thus, the thermally-conductive channel 426 may be aligned with that area of the semiconductor die 408 (e.g., the thermally-conductive channel 426 may contact that area of the semiconductor die 408).

As indicated above, FIG. 7A is provided as an example. Other examples may differ from what is described with respect to FIG. 7A.

FIG. 7B is a cross-sectional view of the example apparatus 400, having the thermally-conductive channel, taken along line X-X (shown in FIG. 4). In particular, FIG. 7B shows the example apparatus 400 with a variation on a quantity of thermally-conductive channels 426. As shown, the semiconductor device assembly 402 may include at least one additional thermally-conductive channel 426 extending through the bore 414 (e.g., extending through the encapsulant 418), and the additional thermally-conductive channel 426 may be configured to transfer heat from the semiconductor die 408 to the circuit board 420, as described above. For example, the semiconductor device assembly 402 may include multiple thermally-conductive channels 426, such as two, three, four, five, or more thermally-conductive channels 426. In some implementations, each thermally-conductive channel 426 may be aligned with a respective area of the semiconductor die 408 that is associated with a higher operating temperature, as described in connection with FIG. 7A.

As indicated above, FIG. 7B is provided as an example. Other examples may differ from what is described with respect to FIG. 7B.

FIG. 7C is a cross-sectional view of the example apparatus 400, having the thermally-conductive channel, taken along line X-X (shown in FIG. 4). In particular, FIG. 7C shows the example apparatus 400 with a variation on a shape of the thermally-conductive channel 426. As shown, the semiconductor device assembly 402 may include a thermally-conductive channel 426 in a shape of an elongated slot. In some implementations, the thermally-conductive channel 426 may be aligned with an area of the semiconductor die 408 that is associated with a higher operating temperature, as described in connection with FIG. 7A. A thermally-conductive channel 426, described herein, is not limited to any particular shape, and may have a cross-section in a shape of a circle, an oval, a square, a rectangle, or the like.

As indicated above, FIG. 7C is provided as an example. Other examples may differ from what is described with respect to FIG. 7C.

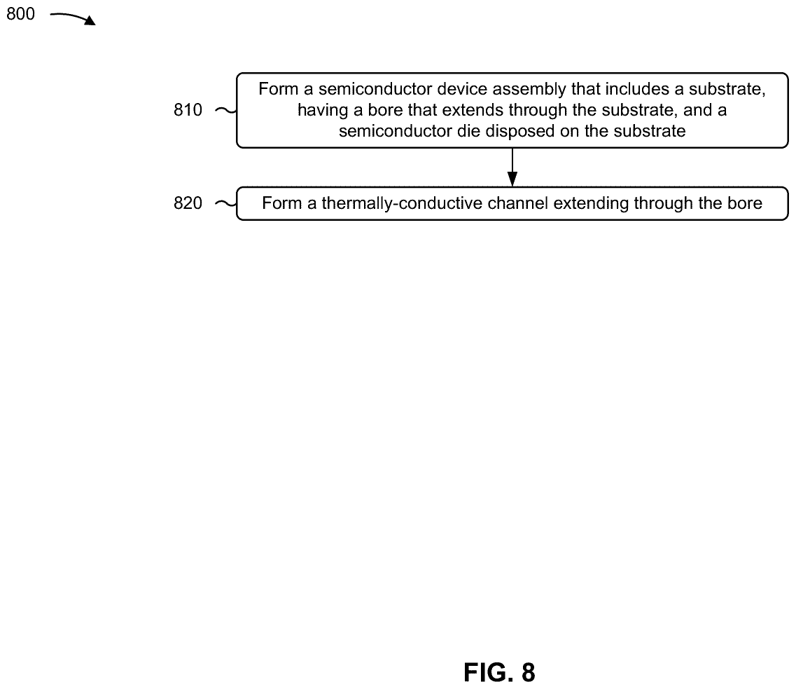

FIG. 8 is a flowchart of an example method 800 of forming an integrated assembly or apparatus having a thermally-conductive channel. In some implementations, one or more process blocks of FIG. 8 may be performed by various semiconductor manufacturing equipment.

As shown in FIG. 8, the method 800 may include forming a semiconductor device assembly that includes a substrate, having a bore that extends through the substrate, and a semiconductor die disposed on the substrate (block 810). As further shown in FIG. 8, the method 800 may include forming a thermally-conductive channel extending through the bore (block 820).

The method 800 may include additional implementations, such as any single implementation or any combination of implementations described below and/or in connection with one or more other methods described elsewhere herein.

In a first implementation, forming the thermally-conductive channel includes forming an encapsulant in the bore, drilling a hole through the encapsulant, and forming the thermally-conductive channel in the hole. For example, the wire bond encapsulant may be formed on the semiconductor device assembly, the wire bond encapsulant may be drilled to form a hole, and the hole may be filled with a thermally-conductive material.

In a second implementation, forming the thermally-conductive channel includes placing the thermally-conductive channel in the bore, and forming an encapsulant in the bore around the thermally-conductive channel. For example, the thermally-conductive channel (e.g., a wire, a rod, or the like) may be installed in a mold cavity for wire bond encapsulant, and wire bond encapsulant may be flowed into the mold.

In a third implementation, forming the thermally-conductive channel includes forming an encapsulant, in the bore, with a hole extending through the encapsulant, and forming the thermally-conductive channel in the hole. For example, wire bond encapsulant may be formed with a hole (e.g., a mold for the wire bond encapsulant may define the hole), and the hole may be filled with a thermally-conductive material.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the semiconductor device assembly 402, an integrated assembly that includes the semiconductor device assembly 402, any part described herein of the semiconductor device assembly 402, and/or any part described herein of an integrated assembly that includes the semiconductor device assembly 402. For example, the method 800 may include forming one or more of the parts 404, 408, 418, 426, and/or 428.

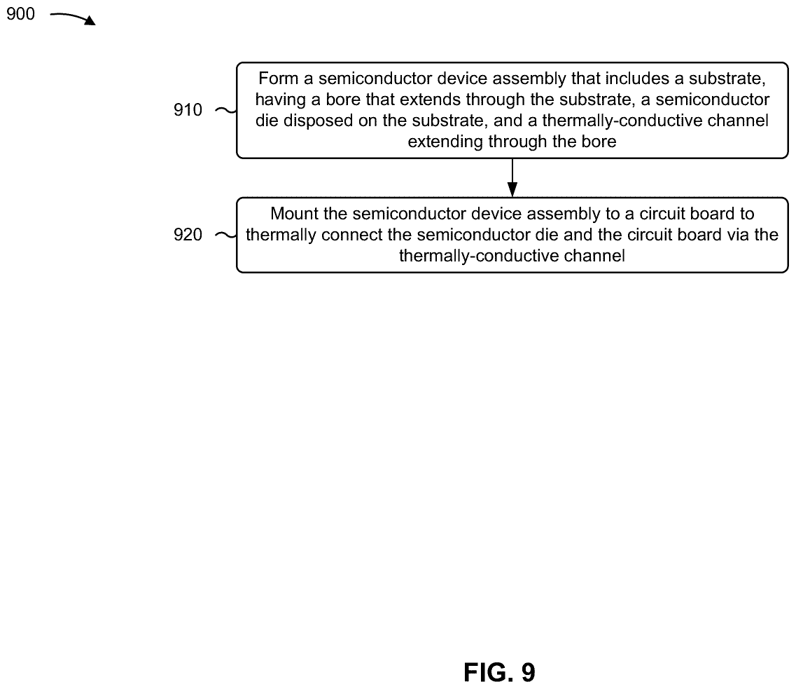

FIG. 9 is a flowchart of an example method 900 of forming an integrated assembly or apparatus having a thermally-conductive channel. In some implementations, one or more process blocks of FIG. 9 may be performed by various semiconductor manufacturing equipment.

As shown in FIG. 9, the method 900 may include forming a semiconductor device assembly that includes a substrate, having a bore that extends through the substrate, a semiconductor die disposed on the substrate, and a thermally-conductive channel extending through the bore (block 910). As further shown in FIG. 9, the method 900 may include mounting the semiconductor device assembly to a circuit board to thermally connect the semiconductor die and the circuit board via the thermally-conductive channel (block 920).

The method 900 may include additional implementations, such as any single implementation or any combination of implementations described below and/or in connection with one or more other methods described elsewhere herein.

In a first implementation, the method 900 may further include performing a reflow procedure to apply solder balls to the substrate.

In a second implementation, alone or in combination with the first implementation, mounting the semiconductor device assembly to the circuit board may include performing an additional reflow procedure to mount the semiconductor device assembly to the circuit board via the solder balls.

In a third implementation, alone or in combination with one or more of the first and second implementations, the method 900 may further include forming the thermally-conductive channel extending through the bore.

In a fourth implementation, alone or in combination with one or more of the first through third implementations, forming the thermally-conductive channel may include the steps described in connection with the first implementation, the second implementation, or the third implementation described in connection with FIG. 8.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the apparatus 400, an integrated assembly that includes the apparatus 400, any part described herein of the apparatus 400, and/or any part described herein of an integrated assembly that includes the apparatus. For example, the method 900 may include forming one or more of the parts 404, 408, 418, 420, 426, 428, and/or 430.

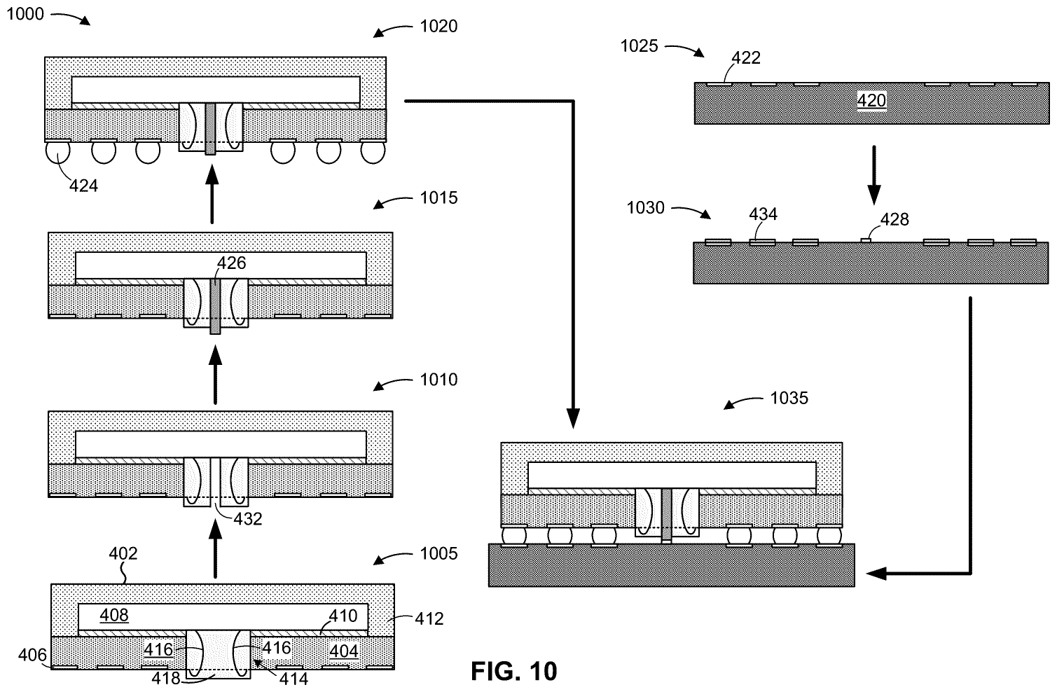

FIG. 10 is a diagram of an example process 1000 for forming an apparatus having a thermally-conductive channel. In particular, process 1000 may be an example of one or more of the methods described in FIG. 8 and/or FIG. 9.

As shown by reference number 1005, process 1000 may include forming the semiconductor device assembly 402 that includes the substrate 404 having the bore 414, the semiconductor die 408 disposed on the substrate, the DAF 410 between the substrate 404 and the semiconductor die 408, the casing 412 surrounding the semiconductor die 408, one or more wire bonds 416 extending between the semiconductor die 408 and the substrate 404 via the bore 414, and/or the encapsulant 418 in the bore 414 and surrounding the wire bond(s) 416, as described above. For example, the semiconductor device assembly 402 may be formed by applying the DAF 410 to the substrate 404, applying the semiconductor die 408 to the DAF 410, forming the casing 412 over the semiconductor die 408, placing the one or more wire bonds 416, and forming the encapsulant 418. The substrate 404 may be formed with the electrical contacts 406 and the bore 414.

As shown by reference number 1010, process 1000 may include drilling a hole 432 in the encapsulant 418. As shown by reference number 1015, process 1000 may include forming the thermally-conductive channel 426 in the hole 432. For example, the thermally-conductive channel 426 may be formed by electrodeposition of a metal, such as copper, in the hole 432. As shown by reference number 1020, process 1000 may include applying the solder balls 424 to the substrate 404 (e.g., to the electrical contacts 406). For example, applying the solder balls 424 to the substrate 404 may include performing a reflow procedure to combine the solder balls 424 and the substrate 404.

As shown by reference number 1025, process 1000 may include forming the circuit board 420 with the electrical contacts 422. As shown by reference number 1030, process 1000 may include applying the TIM 428 and/or solder paste 434 to the circuit board 420 (e.g., to the electrical contacts 422). In some implementations, the steps of process 1000 shown by reference numbers 1025 and 1030 may be performed before or after the steps of process 1000 shown by reference numbers 1005, 1010, 1015, and 1020. As shown by reference number 1035, process 1000 may include mounting (e.g., electrically connecting) the semiconductor device assembly 402 to the circuit board 420. For example, the semiconductor device assembly 402 may be mounted to the circuit board 420 via the solder balls 424. For example, mounting of the semiconductor device assembly 402 to the circuit board 420 may include performing a reflow procedure to combine the semiconductor device assembly 402 and the circuit board 420 using the solder balls 424.

As indicated above, FIG. 10 is provided as an example. Other examples may differ from what is described with respect to FIG. 10.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

In some implementations, a semiconductor device assembly includes a substrate having a bore that extends through the substrate; a semiconductor die disposed on the substrate; and a thermally-conductive channel extending through the bore, the thermally-conductive channel having a first end located at a same side of the substrate as the semiconductor die, and a second end located at an opposite side of the substrate from the semiconductor die.

In some implementations, an apparatus includes a circuit board; and a semiconductor device assembly, including: a substrate having a bore that extends through the substrate, where the substrate is electrically connected to the circuit board; a semiconductor die disposed on the substrate; and a thermally-conductive channel, extending through the bore, between the semiconductor die and the circuit board, where the thermally-conductive channel is configured to transfer heat from the semiconductor die to the circuit board.

In some implementations, a method includes forming a semiconductor device assembly that includes a substrate, having a bore that extends through the substrate, and a semiconductor die disposed on the substrate; and forming a thermally-conductive channel extending through the bore.

In some implementations, a method includes forming a semiconductor device assembly that includes a substrate, having a bore that extends through the substrate, a semiconductor die disposed on the substrate, and a thermally-conductive channel extending through the bore; and mounting the semiconductor device assembly to a circuit board to thermally connect the semiconductor die and the circuit board via the thermally-conductive channel.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “bottom,” “above,” “upper,” “top,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate having a bore that extends through the substrate;
a semiconductor die disposed on the substrate; and
a thermally-conductive channel extending through the bore,
the thermally-conductive channel having a first end located at a same side of the substrate as the semiconductor die, and a second end located at an opposite side of the substrate from the semiconductor die.

2. The semiconductor device assembly of claim 1, wherein the thermally-conductive channel comprises copper.

3. The semiconductor device assembly of claim 1, wherein the semiconductor device assembly is in a board-on-chip configuration.

4. The semiconductor device assembly of claim 1, wherein the first end of the thermally-conductive channel contacts the semiconductor die.

5. The semiconductor device assembly of claim 1, further comprising:
an encapsulant extending through the bore,
wherein the thermally-conductive channel extends through the encapsulant.

6. The semiconductor device assembly of claim 5, further comprising:
a wire bond from a bottom of the semiconductor die to a bottom of the substrate,
wherein the encapsulant encapsulates the wire bond.

7. The semiconductor device assembly of claim 1, wherein the thermally-conductive channel includes a narrower portion and a wider portion.

8. The semiconductor device assembly of claim 1, wherein the thermally-conductive channel is aligned with an area of the semiconductor die that is associated with a higher operating temperature than an operating temperature of another area of the semiconductor die.

9. The semiconductor device assembly of claim 1, further comprising:
an additional thermally-conductive channel extending through the bore.

10. The semiconductor device assembly of claim 1, further comprising:
a casing surrounding the semiconductor die.

11. The semiconductor device assembly of claim 1, further comprising:
a die attach film between the semiconductor die and the substrate.

12. An apparatus, comprising:
a circuit board; and
a semiconductor device assembly, comprising:
a substrate having a bore that extends through the substrate,
wherein the substrate is electrically connected to the circuit board;
a semiconductor die disposed on the substrate; and
a thermally-conductive channel, extending through the bore, between the semiconductor die and the circuit board,
wherein the thermally-conductive channel is configured to transfer heat from the semiconductor die to the circuit board.

13. The apparatus of claim 12, wherein the semiconductor device assembly is in a board-on-chip configuration.

14. The apparatus of claim 12, wherein the substrate is electrically connected to the circuit board via a ball grid array.

15. The apparatus of claim 12, wherein the thermally-conductive channel contacts the semiconductor die.

16. The apparatus of claim 12, further comprising:
a thermal interface material disposed on the circuit board,
wherein the thermally-conductive channel contacts the thermal interface material.

17. The apparatus of claim 12, wherein the thermally-conductive channel includes a narrower portion and a wider portion, and
wherein the wider portion has a thermal connection to the circuit board.

18. The apparatus of claim 12, wherein the thermally-conductive channel has a thermal connection to a via in the circuit board.

19. The apparatus of claim 12, further comprising:
an additional thermally-conductive channel, extending through the bore, between the semiconductor die and the circuit board,
wherein the additional thermally-conductive channel is configured to transfer heat from the semiconductor die to the circuit board.

20. The apparatus of claim 12, wherein a thermal connection of the thermally-conductive channel to the circuit board is at a gap between a first row of electrical contacts of the circuit board and a second row of electrical contacts of the circuit board.

21. The apparatus of claim 12, further comprising:
an encapsulant extending through the bore,
wherein the thermally-conductive channel extends through the encapsulant.

22. A method, comprising:
forming a semiconductor device assembly that includes a substrate, having a bore that extends through the substrate, and a semiconductor die disposed on the substrate; and
forming a thermally-conductive channel extending through the bore.

23. The method of claim 22, wherein forming the thermally-conductive channel comprises:
forming an encapsulant in the bore;
drilling a hole through the encapsulant; and
forming the thermally-conductive channel in the hole.

24. The method of claim 22, wherein forming the thermally-conductive channel comprises:
placing the thermally-conductive channel in the bore; and
forming an encapsulant in the bore around the thermally-conductive channel.

25. The method of claim 22, wherein forming the thermally-conductive channel comprises:
forming an encapsulant, in the bore, with a hole extending through the encapsulant; and
forming the thermally-conductive channel in the hole.
